(19) United States
(12) Patent Application Publication
(10) Pub. No.: US 2005/0181604 A1
(43) Pub. Date: Aug. 18, 2005

(54) Method for structuring metal by means of a carbon mask

(76) Inventors: Hans-Peter Sperlich, Dresden (DE); Lothar Brencher, Radeberg (DE); Jens Bachmann, Dresden (DE)

Correspondence Address: SLATER & MATSIL LLP, 17950 PRESTON ROAD, SUITE 1000, DALLAS, TX, 75252, US

(21) Appl. No.: 11/030,587

(22) Filed: Jan. 6, 2005

Related U.S. Application Data
(63) Continuation of application No. PCT/DE03/02125, filed on Jun. 26, 2003.

(30) Foreign Application Priority Data
Jul. 11, 2002 (DE) 102 31 533.7

(51) Int. Cl. H01L 21/44; H01L 21/3205; H01L 21/302

(52) U.S. Cl. 438/671; 438/669; 438/745; 438/639; 438/585; 438/595

(57) ABSTRACT

A method for structuring metal is disclosed. At least one corrosion-intensive metal layer is deposited on an Si substrate by means of deposition method. An etching mask is then produced on the corrosion-intensive metal layer by photolithographic patterning processes using a resist. The metal layer can then be patterned through the etching mask by means of etching, preferably by plasma etching.

This application is a continuation of co-pending International Application No. PCT/DE03/02125, filed Jun. 26, 2003, which designated the United States and was not published in English, and which is based on German Application No. 102 31 533.7, filed Jul. 11, 2002, both of which applications are incorporated herein by reference.

### TECHNICAL FIELD

The present invention relates generally to semiconductor devices and methods and more particularly to a method for structuring metal by means of a carbon mask.

### BACKGROUND

Conventional metal etching in the semiconductor industry requires the use of a suitable resist mask. Resist masks of this type define the structures for the etching operation, e.g., the spatial boundary of metal structures. For this purpose, first of all a resist layer is applied to the substrate, and then the resist mask is patterned using standard photolithographic patterning processes (e.g., deep ultra violet, i-line, etc.). To achieve particularly small feature sizes, a w/ resist mask is used, suitable for laser direct writing systems or electron beam lithography. The resist masks described can for their part then be used to pattern the functional layer located below the resist mask. Functional layers of this type which have been applied to a substrate in preparatory process steps may be doped or undoped polysilicon layers, SiO₂ layers, metal layers and further functional layers which may be required.

During the etching operation, which is carried out, for example, by plasma etching in a suitable atmosphere, however, the lack of sufficient selectivity means that it is impossible to prevent erosion of the etching mask.

If a metal etch is carried out, for example, in an Al or AlCu layer, during the etching operation sufficient passivation of the structures, which have already been etched must simultaneously be ensured. The byproducts formed during the etching operation, in particular carbon compounds, make it possible to achieve sidewall passivation in the metal structures which have already been etched. This passivation is based on the resist as a carbon source and is enhanced by additives in the etching gas atmosphere, such as N₂, CHF₃, CH₄.

The passivation is required in order to protect the Al structures, which have already been etched from further undesirable corrosion by the etching media during the etching operation which continues further into the depth of the metal layer.

On account of the low selectivity of the etching operation with respect to the metal, the maximum height of the metal layer, which has to be completely etched through, is greatly limited by the thickness of the resist mask.

As has already been stated, during the etching operation this resist mask is also etched away or eroded, and consequently the depth of the metal etch is determined primarily by the thickness of the resist mask. The thickness of the resist mask in turn is limited by other factors, such as the process window for the lithography and the stability.

These problems have led to the development and practical utilization of hard masks for defining the structures in the case of Al etching. Hard masks of this type, which are currently in consist use, for example, of SiO, SiON, W, TiN or combinations of these materials.

The hard masks have on the one hand a considerably higher selectivity compared to standard resist masks, with the result that considerably deeper etching trenches can be produced in metal layers compared to resist masks, depending on further etching parameters. On the other hand, the required sidewall passivation can be achieved more successfully with resist masks, since they supply the required carbon during the etching operation. It has also been found that carbon-rich processes, e.g., caused by the passivating action, are particularly advantageous with regard to the defect density.

The particular drawback of the hard masks is that they cannot supply the carbon required for the sidewall passivation. This has become particularly critical in connection with sputtered Al layers, since considerable corrosion damage has occurred. Also, the carbon required for the sidewall passivation in the case of Al etching cannot be supplied by gases, e.g., CH₄, or at least there are technological limits to the extent to which this can be achieved.

U.S. Pat. No. 5,981,398 has disclosed a process for etching structures in which first of all a hard mask is produced by means of a photoresist and the known photolithographic processes, and this hard mask is then used to pattern a covering layer (blanket target layer).

To enable the etching operation to be carried out using a chlorine-containing plasma, the hard mask consists of materials that are selected from the group consisting of the SOG materials (silsesquioxane spin-on-glass) and amorphous carbon materials. This hard mask layer is first of all deposited on the layer that is to be patterned, which may be a metal layer, by chemical vapor deposition (CVD), physical vapor deposition (PVD) or alternatively HDP-CVD (high-density plasma chemical vapor deposition), and then a resist layer is deposited thereon. In addition, an ARC layer (antireflection coating layer) or a buffer layer will be arranged between the metal layer and the hard mask layer. The ARC layer may be a dielectric SiO₂ layer.

The photoresist is then patterned using one of the known photolithographic processes to form a first mask. Then, the hard mask can be patterned using a fluorine-containing first plasma, so that a second etching mask is formed. The subsequent patterning of the metal layer is then carried out using a chlorine-containing plasma with a high selectivity with respect to the hard mask, so that even relatively thick metal layers (target layers) can be etched using the relatively complex process. The thickness of the hard mask may in this case be much less than the thickness of the target layer. However, a drawback of this process is that a plurality of etching steps have to be carried out using different etching parameters.

The hard mask layer, which contains amorphous carbon and has been deposited by the HDP-CVD process, simultaneously serves as a carbon source and to realize an oxygen-containing etching plasma.

German patent publication 42 01 661 A1 has described a process for producing a semiconductor arrangement, in particular for patterning an AlSiCu thin film on an Si substrate. For this purpose, first of all the Si substrate is coated with a passivation, and then above this with the AlSiCu thin film. A carbon film is deposited directly on the thin film by means of magnetron sputtering. Finally, a resist is applied to the carbon film and patterned by lithography. Then, the carbon film is patterned by reactive ion etching (RIE).

The subsequent etching of the AlSiCu thin film is carried out using the resist pattern and the carbon film pattern using corresponding etching gases and etching rates. Each etching operation here has to be carried out with a predetermined selectivity under in each case specific ambient conditions, making the overall process very complex. There is no provision here for the side flanks of the structures etched into the thin film to be protected. On account of the favorable etching selectivity relationship with respect to the AlSiCu thin film, it is more advantageous to use an additional carbon mask than just to use a resist. The narrowing in the thin-film pattern, which occurs during etching can be varied by stipulating a corresponding radio frequency energy density.

### SUMMARY OF THE INVENTION

The invention is now based on the object of providing a simplified process for metal patterning, in particular for the patterning of Al containing metal layers, with which sufficient passivation of the etched metal structures is ensured by simple means during the etching process.

The object on which the invention is based is achieved, in the case of a process of the type described in the introduction, by the fact that first of all a hard layer in the form of a carbon layer is deposited on the metal layer which has already been deposited and is to be patterned, and then the resist is deposited on the hard layer, that after the patterning of the resist layer the carbon layer is patterned by stripping to form a carbon mask, that the carbon mask which defines the structures is then used to carry out the metal etch with simultaneous sidewall passivation, and that the masks are then stripped.

Pure carbon is preferred for the carbon layer, although silicon carbide (SiCH) or silicon oxycarbide (SiOC) are also used, it being possible to use SiCH.

A W cap layer can additionally be deposited between the carbon layer and the resist.

Particular advantages of the invention are considered to reside in the fact that the hard mask, in accordance with the invention, now fulfills a number of functions, in that firstly the structures, which are to be etched, are defined and, at the same time, a rich source of carbon is provided for the sidewall passivation of the etched metal structures. A suitable protection by the sidewall passivation compared to the hard masks, which have otherwise customarily been used, such as for example SiO, SiON, etc., is achieved, with the result that the known Al corrosion problems are avoided.

Furthermore, the metal patterning is also significantly simplified by the fact that the etching stop layer which is otherwise additionally required, e.g., a dielectric ARC layer, can be dispensed with if the hard mask consists of SiCH, since this layer is sufficiently resistant to oxygen.

### BRIEF DESCRIPTION OF THE DRAWINGS

The invention is to be explained in more detail below on the basis of an exemplary embodiment. In the associated drawings:

FIG. 1 shows a stack which has been built up on an Si substrate, comprising a carbon hard mask and a cap layer above it and a resist located on the latter;

FIG. 2 shows the stack after the lithography using the patterned resist;

FIG. 3 shows the stack after the opening of the hard mask and of the cap layer;

FIG. 4 shows the stack after the metal etch with a remainder of the hard mask and a polymer layer in the etching trenches;

FIG. 5 shows the stack after the hard mask has been stripped; and

FIG. 6 shows the stack with patterned metal layer after the removal of the polymer.

### DETAILED DESCRIPTION OF ILLUSTRATIVE EMBODIMENTS

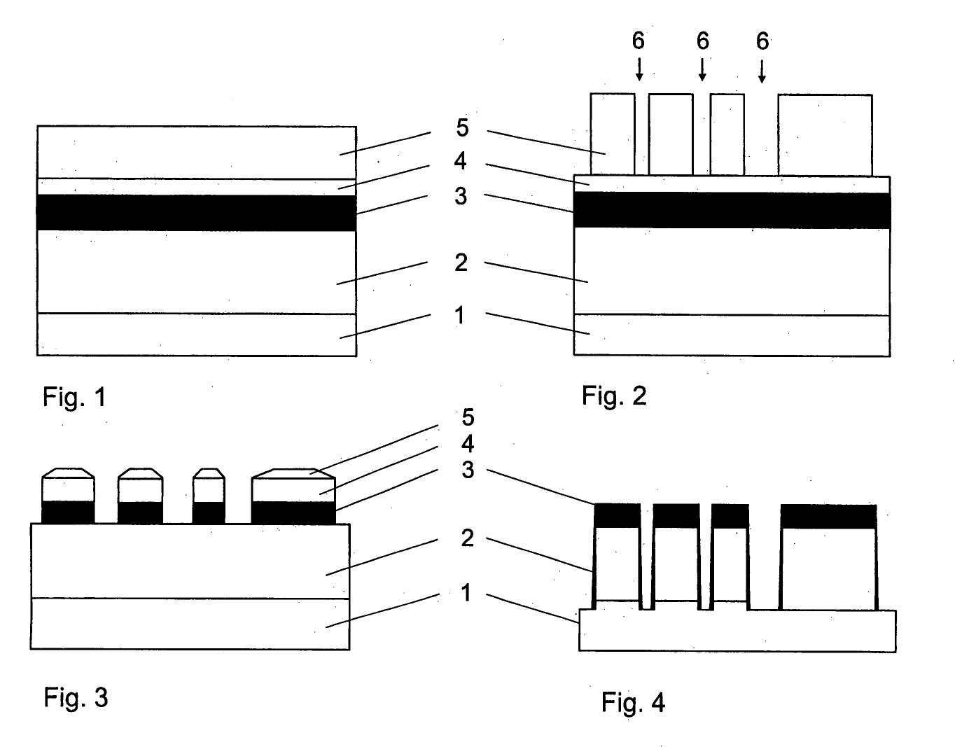

FIG. 1 diagrammatically depicts a layer structure, which is to be patterned on an Si substrate 1. An AlCu metal layer 2 has been deposited on the Si substrate 1 by means of a conventional CVD process. This metal layer 2 comprises a stack of a thin film of Ti (around 50 nm), an AlCu layer with a thickness of around 1000 nm, on which there is a thin film of TiN (around 40 nm). Alternatively, the metal layer 2 may also comprise a stack comprising a very thin film of Ti (around 10 nm), a thicker layer of AlCu (around 400 nm), a further very thin film of Ti (around 5 nm) and a TiN layer (around 40 nm).

On this metal layer 2 there is a carbon layer 3 with a thickness of around 200 to 500 nm, which is followed, in turn, by a w/ cap layer 4 (SiON) and then a resist 5. The cap layer 4 is used as a stop layer during the lithography.

FIG. 2 shows the layer structure shown in FIG. 1 after the resist 5 has been patterned photolithographically, e.g., by means of DUV (deep ultraviolet), i-line, etc. Then, the cap layer 4 and the carbon layer 3 below it can be etched in situ, i.e., in the same process step. The result is the hard mask illustrated in FIG. 3, which is used directly for patterning of the metal layer 2 by metal etching.

FIG. 4 illustrates the layer structure after the metal etch, the metal layer 2 having been completely etched through. The etching trench 6 extends into the substrate 1. The carbon mask, which defines the structures, is used to carry out the metal etch of the metal layer (2) with simultaneous sidewall passivation. Accordingly, carbon can extend on the passivated sidewalls of the metal layer 2, as shown in FIG. 4.

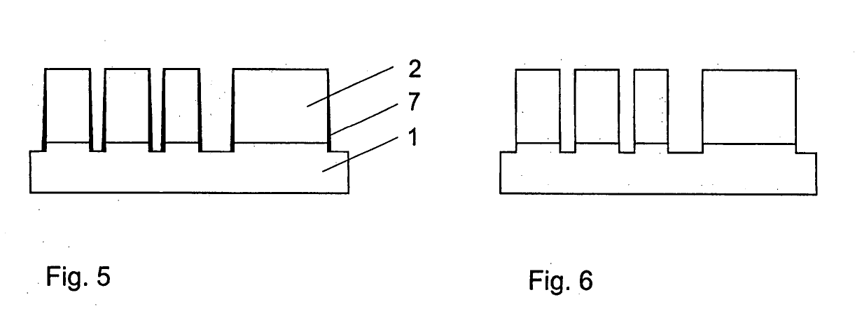

Then, the remainder of the carbon layer 3 is stripped in situ. Any etching residues 7 present in the etching trenches can be removed, e.g., by wet-chemical means (FIGS. 5, 6).

Finally, FIG. 6 shows the finished metal structure after the process according to the invention.

In summary, the preferred embodiment of the present invention provides a process for metal patterning, in which at least one corrosion-intensive AlCu metal layer is deposited on an Si substrate by means of CVD deposition processes, then an etching mask is produced on the corrosion-intensive metal layer by photolithographic patterning processes using a resist, and then the metal layer is patterned through the etching mask by means of etching, preferably by plasma etching. This process is characterized in that first of all a hard layer in the form of a carbon layer 3 made of silicon carbide (SiCH) is deposited on the metal layer 2 having a thickness of about 1000 nm which has already been deposited and is to be patterned, in that the resist 5 is deposited on the carbon layer 3, in that after the patterning of the resist 5 the carbon layer 3 is patterned by etching to form a carbon mask and in that the carbon mask, which defines the structures, is then used to carry out the metal etch of the metal layer 2 with simultaneous sidewall passivation by means of the carbon compounds formed during the etching process, and in that the rest of the carbon layer ) is then stripped in situ, and the etching residues are removed wet-chemically.

1. A method for patterning a metal layer, the method comprising:
depositing a metal layer over a substrate;
depositing a carbon layer over the metal layer;
forming a patterned resist layer over the carbon layer;
creating a carbon mask by patterning the carbon layer in alignment with the patterned resist mask; and
performing an etching process that simultaneously etches the metal layer using the carbon mask and passivates sidewalls of the etched metal layer with carbon containing material formed during the etching process.

2. The method of claim 1 and further comprising removing remaining portions of the carbon layer from upper and sidewall surfaces of the etched metal layer.

3. The method of claim 2 and further comprising performing a wet chemical process to remove any etching residues after performing the etching process.

4. The method of claim 1 wherein depositing a metal layer comprises depositing an AlCu layer.

5. The method of claim 1 wherein depositing a metal layer comprises depositing a metal layer using a chemical vapor deposition process.

6. The method of claim 1 wherein depositing a metal layer comprises depositing a metal layer having a thickness of about 1000 nm.

7. The method of claim 1 wherein the carbon layer comprises silicon carbide.

8. The method of claim 1 wherein the carbon layer comprises pure carbon.

9. The method of claim 1 wherein the carbon layer is produced from silicon oxycarbide (SiOC).

10. The method of claim 1 wherein the carbon layer is produced from a mixture of silicon carbide and silicon oxycarbide.

11. The method of claim 1 and further comprising depositing a cap layer over the carbon layer prior to forming a patterned resist layer.

12. The method of claim 11 wherein the cap layer comprises SiON.

13. A process for metal patterning, the process comprising:
depositing at least one corrosion-intensive AlCu metal layer over a silicon substrate by means of a chemical vapor deposition processes;
depositing a hard layer in the form of a carbon layer made of silicon carbide on the metal layer;
producing an etching mask over the corrosion-intensive metal layer by photolithographic patterning processes using a resist, the resist being deposited on the carbon layer;
patterning the carbon layer using the resist to create a carbon mask;
patterning the metal layer through the carbon mask by means of etching, wherein the etching simultaneously passivates sidewalls of the patterned metal layer with carbon containing material formed during the etching process;
stripping remaining portions of the carbon layer; and
removing any etching residues by performing a wet-chemical process.

14. The process as claimed in claim 13, wherein the carbon layer is produced from silicon oxycarbide (SiOC).

15. The process as claimed in claim 13, wherein the carbon layer is produced from a mixture of silicon carbide and silicon oxycarbide.

16. The process as claimed in claim 13, wherein the metal layer has a thickness of about 1000 nm.

17. The process as claimed in claim 13, and further comprising depositing a cap layer between the carbon layer and the resist.

18. The process as claimed in claim 17, wherein the cap layer comprises SiON.

19. The process as claimed in claim 13, wherein patterning the metal by means of etching comprises patterning the metal by means of plasma etching.
